(19) United States
(12) Patent Application Publication
(10) Pub. No.: US 2006/0208298 A1
(43) Pub. Date: Sep. 21, 2006

(54) MEMORY CELL OF DYNAMIC RANDOM ACCESS MEMORY AND ARRAY STRUCTURE THEREOF

(76) Inventors: Ko-Hsing Chang, Hsinchu (TW); Chia-Chiang Wang, Taichung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,222

(22) Filed: Oct. 11, 2005

(30) Foreign Application Priority Data
Mar. 17, 2005 (TW) 94108145

(51) Int. Cl. H01L 29/94

(52) U.S. Cl. 257/301

(57) ABSTRACT

A DRAM cell including a trench capacitor structure, a transistor and a stacked capacitor structure is provided. A first electrode of the trench capacitor structure is disposed in the substrate at the bottom of a trench. A second electrode of the trench capacitor structure is disposed in the trench. The transistor includes a gate, first and second source/drain regions. The gate is disposed on the substrate beside the trench capacitor structure. The first and the second source/drain regions are disposed in the substrate on respective sides of the gate. A third electrode of the stacked capacitor structure is disposed on the substrate between the gate of the transistor and the trench capacitor structure. A fourth electrode of the stacked capacitor structure is disposed on the third electrode above the substrate. The first electrode connects electrically with the fourth electrode, and the second electrode connects electrically with the third electrode.

### CROSS-REFERENCE TO RELATED APPLICATION

This application claims the priority benefit of Taiwan application serial no. 941 08145, filed on Mar. 17, 2005. All disclosure of the Taiwan application is incorporated herein by reference.

### BACKGROUND OF THE INVENTION

1. Field of the Invention

The present invention relates to a dynamic random access memory. More particularly, it relates to a memory cell of a dynamic random access memory and an array structure thereof.

2. Description of the Related Art

As semiconductor production process into the deep sub-micron technology, the size of each device also shrinks considerably. In the case of a dynamic random access memory (DRAM), the space available for fabricating a capacitor is reduced. However, with the increasing size of computer software, the demand for larger memory storage capacity is significantly increased. Since larger memory storage capacity runs counter with smaller space requirements, some modifications of the method of fabricating the DRAM capacitor are needed.

DRAM can be categorized according to the type of capacitor structure into stacked capacitor type DRAM and deep trench capacitor type DRAM. A stacked capacitor is a structure disposed above the transistor of a DRAM. To increase the integration level, however, the deep trench capacitor has been developed such that the capacitor is fabricated within the substrate to reduce substrate surface area. Yet, with the rapid development of new technologies, the demand for higher capacitance in capacitors has increased. With the need to miniaturize semiconductor devices, any increase in the area of a capacitor, whether it is a stacked capacitor or a deep trench capacitor, will adversely affect the integration level. Thus, providing a capacitor having a higher capacitance per unit area is one of the major goals of the industry.

### SUMMARY OF THE INVENTION

Accordingly, at least one objective of the present invention is to provide a memory cell for a DRAM. The memory cell integrates the design of a stacked capacitor structure with that of a trench capacitor structure so that the two capacitors are serially connected to increase overall capacitance of the memory unit.

At least a second objective of the present invention is to provide an array structure for a DRAM capable of increasing the capacitance of an individual memory cell but without increasing the area occupied by the wafer so that the integration level is increased.

To achieve these and other advantages, and in accordance with the purpose of the invention, as embodied and broadly described herein, the invention provides a memory cell for a DRAM. The memory cell includes a trench capacitor structure, a transistor and a stacked capacitor structure. The trench capacitor structure is disposed in a trench within a substrate. The trench capacitor structure has a first electrode and a second electrode. The first electrode is disposed in the substrate at the bottom of the trench, and the second electrode is disposed within the trench. The transistor has a gate, a first source/drain region and a second source/drain region. The gate is disposed on the substrate beside the trench capacitor structure, and the first source/drain region and the second source/drain region are disposed in the substrate on the respective sides of the gate. The first source/drain region of the transistor is electrically connected to the trench capacitor structure. The stacked capacitor structure has a third electrode and a fourth electrode. The third electrode is disposed on the substrate between the gate of the transistor and the trench capacitor structure. The fourth electrode is disposed on the third electrode above the substrate. The stacked capacitor structure is electrically connected to the first source/drain region of the transistor. The first electrode connects electrically with the fourth electrode, and the second electrode connects electrically with the third electrode.

According to the embodiment of the present invention, the memory cell in the aforementioned DRAM further includes a conductive strap disposed in the substrate between the gate of the transistor and the trench capacitor structure and beside the trench capacitor structure. The conductive strap electrically connects the trench capacitor structure with the first source/drain region of the transistor. The conductive strap includes a buried strap (BS).

According to the embodiment of the present invention, the aforementioned trench capacitor structure further includes a first capacitor dielectric layer disposed between the first electrode and the second electrode. The first capacitor dielectric layer is fabricated using silicon nitride or silicon oxide.

According to the embodiment of the present invention, the first electrode includes an N-doped region.

According to the embodiment of the present invention, the second electrode includes a doped polysilicon layer.

According to the embodiment of the present invention, the aforementioned stacked capacitor structure further includes a second capacitor dielectric layer disposed between the third electrode and the fourth electrode. The second capacitor dielectric layer is fabricated using silicon nitride or silicon oxide.

According to the embodiment of the present invention, the third electrode includes a doped polysilicon layer.

According to the embodiment of the present invention, the fourth electrode includes a doped polysilicon layer.

According to the embodiment of the present invention, the aforementioned memory cell further includes a buried N-well disposed in the substrate and electrically connected to the first electrode, a conductive structure disposed on the substrate and electrically connected to the fourth electrode, and an n-doped region disposed in the substrate and electrically connected to the buried N-well and the conductive structure.

The present invention also provides an array structure for a DRAM. The array structure includes a substrate, a plurality of memory cells, a plurality of bit lines and a plurality of word lines. The substrate has a plurality of isolation structures that define a plurality of linear active regions. Furthermore, each pair of memory cells is located on one linear active region. The bit lines are disposed to form columns, with each bit line serially connecting the two memory cells within the active regions. The word lines are set in a direction perpendicular to the bit lines, crossing over each isolation structure in the adjacent column to connect with the memory cells in the same row. The aforementioned memory cell further includes a trench capacitor structure, a transistor and a stacked capacitor structure. The trench capacitor structure is disposed in the trench within the substrate. The trench capacitor structure has a first electrode and a second electrode. The first electrode is disposed in the substrate at the bottom of the trench, and the second electrode is disposed in the trench. The transistor has a gate, a first source/drain region and a second source/drain region. The gate is disposed on the substrate beside the trench capacitor structure. The first source/drain region is disposed in the substrate between the gate and the trench capacitor structure. The second source/drain region is disposed in the substrate beside the gate. The stacked capacitor structure has a third electrode and a fourth electrode. The third electrode is disposed on the substrate between the gate of the transistor and the trench capacitor structure, and the fourth electrode is disposed on the third electrode above the substrate.

The DRAM in the present invention has memory cells including a serially connected trench capacitor structure and stacked capacitor structure therein. Hence, the capacitance of the memory cells inside the DRAM is significantly increased. In addition, the present invention does not increase the area occupied by the DRAM memory cells on the wafer. Hence, the integration level of the DRAM can be increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view showing the array structure of a DRAM according to one embodiment of the present invention.

FIG. 2 is a schematic cross-sectional view along line I-I′ of FIG. 1 showing a memory cell in the DRAM.

FIG. 3 is an equivalent circuit diagram of a memory cell in a DRAM according to one embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

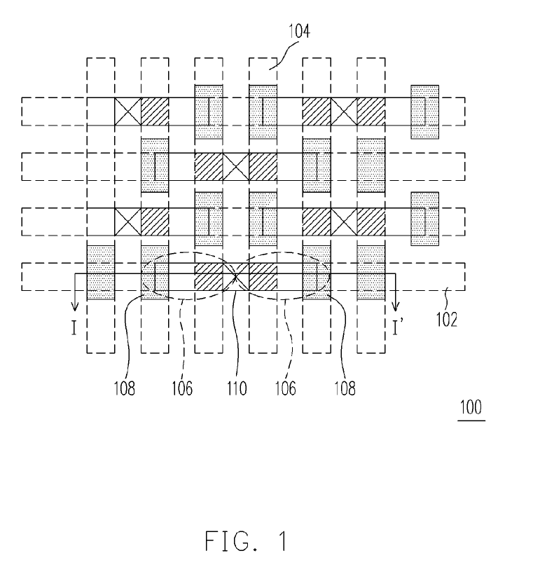

FIG. 1 is a top view showing the array structure of a DRAM according to one embodiment of the present invention. As shown in FIG. 1, the array structure of a DRAM according to the present invention includes a substrate 100, a plurality of bit lines 102, a plurality of word lines 104 and a plurality of memory cells 106. The substrate 100 also has a plurality of isolation structures 108. The isolation structures 108 are shallow trench isolation (STI) structures, for example. The isolation structures 108 define a plurality of linear active regions 110. Each linear active region 110 further includes a pair of memory cells 106.

The bit lines 102 are disposed on the substrate 100 and aligned to form a column. Each bit line 102 serially connects two memory cells 106 in each linear active region 110. In other words, the bit lines 102 are disposed in parallel on the linear active region 110. Furthermore, the two adjacent memory cells 106 on each linear active region 110 share a bit line 102.

In addition, the word lines 104 are disposed on the substrate 100. Moreover, the word lines 104 are disposed in a direction perpendicular to the bit lines 102, for example. The linear active region 110 between each column is alternately laid. Each word line 104 crosses over the isolation structures 108 of the adjacent column and serially connects with the memory cells 106 in the same row.

As shown in FIG. 1, the disposition of the array structure in the DRAM in the present invention is such that each linear active region 110 includes two memory cells 106. Furthermore, the memory cells 106 are disposed to form a hexagon, for example.

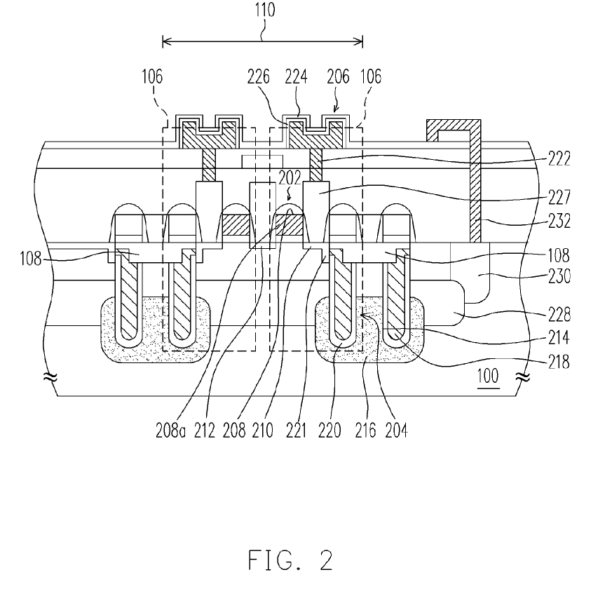

FIG. 2 is a schematic cross-sectional view along line I-I′ of FIG. 1 showing a memory cell in the DRAM. As shown in FIG. 2, each memory cell 106 in the DRAM of the present invention includes a transistor 202, a trench capacitor structure 204 and a stacked capacitor structure 206. The trench capacitor structure 204 is disposed in the trench 214 within the substrate 100. The trench capacitor structure 204 has a first electrode 216 and a second electrode 218. The first electrode 216 is disposed in the substrate 100 at the bottom of the trench 214, and the second electrode 218 is disposed within the trench 214. The electrode 216 of the trench capacitor structure 204 is fabricated, for example, by forming an N-doped region in the substrate 100 at the bottom of the trench 214. The electrode 218 of the trench capacitor structure 204 is a conductive layer made of doped polysilicon, for example. Furthermore, the trench capacitor structure 204 further includes a capacitor dielectric layer 220 disposed between the first electrode 216 and the second electrode 218. The capacitor dielectric layer 220 is fabricated using silicon oxide or silicon nitride, for example.

The transistor 202 in the memory cell 106 includes a gate 208 and source/drain regions 210 and 212. The gate 208 is disposed on the substrate 100 beside the trench capacitor structure 204. The source/drain regions 210 and 212 are disposed in the substrate 100 on the respective sides of the gate 208. Furthermore, the source/drain region 210 of the transistor 202 is electrically connected to the trench capacitor structure 204. Note that the conductive layer 208a in the gate 208 is actually the word line 104 shown in FIG. 1.

In one embodiment, the memory cell 106 of the DRAM further includes a conductive strap 221, such as a buried strap (BS). The conductive strap 221 is disposed in the substrate 100 between the gate 208 of the transistor 202 and the trench capacitor structure 204. Moreover, the conductive strap 221 is located on one side of the trench capacitor 204 and electrically connects the trench capacitor structure 204 and the source/drain region 210 of the transistor 202.

The stacked capacitor structure 206 of the memory cell 106 has a first electrode 222 and a second electrode 224. The first electrode 222 is disposed on the substrate 100 between the gate 208 of the transistor 202 and the trench capacitor structure 204. The second electrode 224 is disposed on the substrate 100 above the first electrode 222. Furthermore, the stacked capacitor structure 206 is electrically connected to the source/drain region 210 of the transistor 202 through the first electrode 222. The electrodes 222 and 224 of the stacked capacitor structure 206 are conductive layers fabricated using doped polysilicon, for example. In addition, the stacked capacitor structure 206 further includes a capacitor dielectric layer 226. The capacitor dielectric layer 226 is disposed between the first electrode 222 and the second electrode 224. The capacitor electrode 226 is fabricated using silicon oxide or silicon nitride, for example. In another embodiment, a contact structure 227 can also be disposed between the first electrode 222 of the stacked capacitor structure 206 and the substrate 100 to connect the stacked capacitor structure 206 and the transistor 202.

Although the electrode 222 of the stacked capacitor structure 206 is illustrated in a cylindrical shape shown in FIG. 2, the shape of the electrode 222 is not limited to such a shape. In the present invention, there is no particular restriction on the shape of the electrode 222 in the stacked capacitor structure 206. Aside from a cylindrical shape, the electrode 222 can have a shape like a crown, fin, or spread. In addition, a hemispherical grain (HSG) layer (not shown) may also be formed on the surface of the electrode 222 to increase its surface area and the capacitance of the memory cell 106.

Note that in the present invention, the electrode 218 of the trench capacitor structure 204 and the electrode 222 of the stacked capacitor structure 206 in the memory cell 106 are electrically connected, and the electrode 216 of the trench capacitor structure 204 and the electrode 224 of the stacked capacitor structure 206 are electrically connected as well. In other words, the trench capacitor structure 204 and the stacked capacitor structure 206 are connected in parallel. In details, the electrode 218 of the trench capacitor structure 204 is in contact with the source/drain region 210 of the transistor 202 so that the source/drain region 210 of the transistor 202 is connected to the electrode 222 of the stacked capacitor structure 206. Thus, the electrode 218 of the trench capacitor structure 204 is electrically connected to the electrode 222 of the stacked capacitor structure 206. An alternative method of electrically connecting the electrode 216 of the trench capacitor structure 204 with the electrode 224 of the stacked capacitor structure 206 includes forming a buried N-well 228 in the substrate 100, for example. The buried N-well 228 and the electrode 216 of the trench capacitor structure 216 are connected. Thereafter, an N-doped region 230 is formed in the substrate 100 to connect with the buried N-well 228. After that, a conductive structure 232 is formed on the N-doped region 230 to connect with the electrode 224 of the stacked capacitor structure 206. Thus, the electrode 216 of the trench capacitor structure 204 is electrically connected to the electrode 224 of the stacked capacitor structure 206. In one embodiment, another N-doped region (not shown) with a higher dopant concentration may be formed within the N-doped region 230 underneath the conductive structure 232 to electrically connect the electrode 216 of the trench capacitor structure 204 with the electrode 224 of the stacked capacitor structure 206.

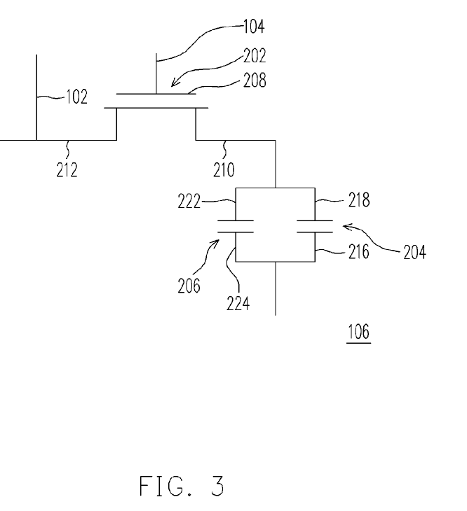

FIG. 3 is an equivalent circuit diagram of a memory cell in a DRAM according to one embodiment of the present invention. The circuit diagram is based on the memory cell in the DRAM shown in FIG. 2. In the simplified circuit diagram of the memory cell 106, the gate 208 of the transistor 202 is coupled to a word line 104. The source/drain region 212 is coupled to the bit line 102, and the source/line 210 is coupled to the trench capacitor structure 204 and the stacked capacitor structure 206. In details, the source/drain region 210 is coupled to the electrode 218 of the trench capacitor structure 204 and the electrode 224 of the stacked capacitor structure 206. In other words, in the memory cell 106 the trench capacitor structure 204 and the stacked capacitor structure 206 are connected in parallel.

In summary, the present invention includes at least the following advantages: 1. The capacitor structures inside the memory cell of the DRAM are connected in parallel so that the memory cell can have higher capacitance. 2. The memory cell of the DRAM can have a higher capacitance without increasing the area occupied by the capacitor structures on the wafer. Thus, a higher integration level of the devices can be achieved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A memory cell of DRAM, comprising:
a trench capacitor structure disposed within a trench in a substrate, wherein the trench capacitor structure has a first electrode and a second electrode such that the first electrode is disposed in the substrate at the bottom of the trench and the second electrode is disposed in the trench;
a transistor having a gate, a first source/drain region and a second source/drain region, wherein the gate is disposed on the substrate on one side of the trench capacitor structure, the first source/drain region and the second source/drain region are disposed in the substrate on the sides of the gate, and the first source/drain region of the transistor connects electrically with the trench capacitor structure; and
a stacked capacitor structure having a third electrode and a fourth electrode, wherein the third electrode is disposed on the substrate between the gate of the transistor and the trench capacitor structure, the fourth electrode is disposed on the third electrode above the substrate, and the stacked capacitor structure connects electrically with the first source/drain region of the transistor,
wherein the first electrode connects electrically with the fourth electrode and the second electrode connects electrically with the third electrode.

2. The memory cell of claim 1, wherein the memory cell further comprises a conductive strap disposed in the substrate between the gate of the transistor and the trench capacitor structure and located on one side of the trench capacitor structure, and the conductive strap connects electrically with the trench capacitor structure and the first source/drain region of the transistor.

3. The memory cell of claim 2, wherein the conductive strap comprises a buried strap (BS).

4. The memory cell of claim 1, wherein the trench capacitor structure further comprises a first capacitor dielectric layer disposed between the first electrode and the second electrode.

5. The memory cell of claim 3, wherein a material of the first capacitor dielectric layer comprises silicon oxide or silicon nitride.

6. The memory cell of claim 1, wherein the first electrode comprises an N-doped region.

7. The memory cell of claim 1, wherein the second electrode comprises a doped polysilicon layer.

8. The memory cell of claim 1, wherein the stacked capacitor structure further comprises a second capacitor dielectric layer disposed between the third electrode and the fourth electrode.

9. The memory cell of claim 8, wherein a material of the second capacitor dielectric layer comprises silicon nitride or silicon oxide.

10. The memory cell of claim 1, wherein the third electrode comprises a doped polysilicon layer.

11. The memory cell of claim 1, wherein the fourth electrode comprises a doped polysilicon layer.

12. The memory cell of claim 1, wherein the memory cell further comprises a buried N-well disposed in the substrate electrically connected to the first electrode; a conductive structure disposed on the substrate electrically connected to the fourth electrode; and an N-doped region disposed in the substrate electrically connected to the buried N-well and the conductive structure.

13. An array structure of DRAM, comprising:
a substrate having a plurality of isolation structures therein for defining a plurality of linear active regions;
a plurality of memory cells with a pair of memory units disposed on each linear active region, wherein each memory cell comprises:
a trench capacitor structure disposed within a trench in a substrate, wherein the trench capacitor structure has a first electrode and a second electrode such that the first electrode is disposed in the substrate at the bottom of the trench and the second electrode is disposed in the trench;
a transistor having a gate, a first source/drain region and a second source/drain region, wherein the gate is disposed on the substrate on one side of the trench capacitor structure, the first source/drain region and the second source/drain region are disposed in the substrate on the respective sides of the gate, and the first source/drain region of the transistor connects electrically with the trench capacitor structure; and
a stacked capacitor structure having a third electrode and a fourth electrode, wherein the third electrode is disposed on the substrate between the gate of the transistor and the trench capacitor structure, and the fourth electrode is disposed on the third electrode above the substrate,
a plurality of bit lines aligned to form a column and each bit line serially connects two memory cells in each linear active region; and
a plurality of word lines aligned in a direction perpendicular to the bit lines, crossing over each isolation structure of an adjacent column and each word line serially connects with the memory cells in the same row.

14. The array structure of claim 13, wherein the array structure further comprises a conductive strap disposed in the substrate between the gate of the transistor and the trench capacitor structure and located on one side of the trench capacitor structure.

15. The array structure of claim 14, wherein the conductive strap comprises a buried strap.

16. The array structure of claim 13, wherein the trench capacitor structure further comprises a first capacitor dielectric layer disposed between the first electrode and the second electrode.

17. The array structure of claim 16, wherein a material of the first capacitor dielectric layer comprises silicon nitride or silicon oxide.

18. The array structure of claim 13, wherein the first electrode comprises an N-doped region.

19. The array structure of claim 13, wherein the second electrode comprises a doped polysilicon layer.

20. The array structure of claim 13, wherein the stacked capacitor structure further comprises a second capacitor dielectric layer disposed between the third electrode and the fourth electrode.

21. The array structure of claim 20, wherein a material of the second capacitor dielectric layer comprises silicon nitride or silicon oxide.

22. The array structure of claim 13, wherein the third electrode comprises a doped polysilicon layer.

23. The array structure of claim 13, wherein the fourth electrode comprises a doped polysilicon layer.
